(19) United States
(12) Patent Application Publication
(10) Pub. No.: US 2021/0313508 A1
(43) Pub. Date: Oct. 7, 2021

(54) LINEAR PIEZOELECTRIC MOTOR CAPABLE OF UNDERWATER DRIVING AND METHOD OF MANUFACTURING SAME

(71) Applicant: ECO DM LAB Co., Ltd., Cheongju-si (KR)

(72) Inventors: Man Soon YOON, Cheongju-si (KR); Young Min PARK, Cheongju-si (KR)

(21) Appl. No.: 17/219,872

(22) Filed: Mar. 31, 2021

(30) Foreign Application Priority Data
Apr. 1, 2020 (KR) 10-2020-0039552

(51) Int. Cl. H01L 41/053; H01L 41/09

(52) U.S. Cl. CPC H01L 41/0533; H01L 41/098

(57) ABSTRACT

Disclosed is a linear piezoelectric motor having a waterproof function. A coupler is provided inside a housing, and a moving shaft is fixed to a piezoelectric actuator by the coupler. A fastening unit is provided on a side surface of the moving shaft passing through the housing and in a concave recessed part of the housing. The fastening unit is provided with an elastic tube and a tension spring, and the moving shaft inserted into the elastic tube is inserted into an insertion hole of the housing.

### BACKGROUND

### 1. Technical Field

The present disclosure relates to a linear piezoelectric motor, and more particularly, to a linear piezoelectric motor that may be used under water and has improved driving stability even with a change in water temperature.

### 2. Related Art

Piezoelectric motors are motors that use the piezoelectric effect of piezoelectric ceramics that cause vibrations by a change in applied electric field. The piezoelectric motors may be advantageously operated without noise using a frequency in an ultrasonic range of 20 kHz or more that cannot be detected by the human ear.

The conventional piezoelectric motors are implemented in a vibration transmission method such as a traveling wave method or a standing wave method, and in the vibration transmission method, abrasion occurs at a contact part due to repeated driving. The abrasion of the contact part becomes an obstacle to securing a constant amplitude and is one factor that shortens the lifetime of the piezoelectric motors. In order to overcome the disadvantages of the vibration transmission method, a linear piezoelectric motor that linearly moves a moving body has been developed. The initial form of a linear piezoelectric motor is a structure in which a moving shaft is joined to a piezoelectric ceramic, and the moving body is mounted on the moving shaft. In the initial linear piezoelectric motor, since the piezoelectric ceramic is formed in a planar type, an elastic plate needs to be joined to the piezoelectric ceramic in order to obtain displacement. Such a structure causes an increase of manufacturing costs and a complex manufacturing process.

The inventor of the present invention has proposed a linear piezoelectric motor using a dome-type actuator in Korean Patent No. 10-0768513.

In the above patent, in the linear piezoelectric motor, the moving shaft is joined to an apex of the dome-type piezoelectric actuator by using epoxy. The junction portion of the apex of the dome-type piezoelectric actuator and the moving shaft corresponds to point contact, and the junction portion is vulnerable. In particular, since vibrations of the dome-type piezoelectric actuator are transferred to a carbon rod that is the moving shaft, a crack occurs at a contact point between the carbon rod and the dome-type piezoelectric actuator. In this case, heat is generated by vibrational energy, the epoxy is weakened or cracks are generated, and thus the moving shaft is separated from the dome-type piezoelectric actuator.

In particular, when the linear piezoelectric motor is driven under water, the moving shaft is driven under water. However, since the piezoelectric actuator and a coupler should avoid coming into contact with water, a structure is adopted in which the inflow of water is blocked by a specific housing. In this case, in order to block the inflow of water along with the moving shaft protruding outside the housing, an adhesive fills a concave surface of the housing, and the inflow of water is prevented. However, the moving shaft adhered to the adhesive is vibrated by ultrasonic vibrations, and spacing occurs according to a change in water temperature due to a thermal expansion coefficient. Thus, water flows the spacing between the moving shaft and the adhesive.

### SUMMARY

The purpose of the present disclosure is to provide a linear piezoelectric motor having an excellent waterproof function by which water does not penetrate even in an underwater environment.

The present disclosure provides a linear piezoelectric motor including: a housing having a recessed part and an insertion hole in an upper portion thereof; a lower substrate fixed to a bottom surface of the housing; a piezoelectric actuator that has a dome shape, is fixed to the lower substrate, and performs thickness vibration by an applied voltage; a coupler formed on the piezoelectric actuator; a moving shaft fixed to an upper surface of the piezoelectric actuator through a through-hole of the coupler; and a fastening unit that is formed in the recessed part of the housing and blocks water leakage between the insertion hole and the moving shaft passing through the housing through the insertion hole.

The present disclosure also provides a linear piezoelectric motor including: a piezoelectric actuator that performs vibration by an applied voltage; a lower substrate that fixes the piezoelectric actuator; a moving shaft that performs vibration in a lengthwise direction by the piezoelectric actuator; a coupler that connects the moving shaft and the piezoelectric actuator; a housing in which the piezoelectric actuator, the lower substrate, and the coupler are accommodated and through which the moving shaft passes through an insertion hole; and a fastening unit that is disposed in a concave recessed part of the housing, surrounds a side surface of the moving shaft, and prevents external water from penetrating into the housing.

### BRIEF DESCRIPTION OF DRAWINGS

Exemplary embodiments of the present disclosure will become more apparent by describing exemplary embodiments of the present disclosure in detail with reference to the accompanying drawings, in which:

FIG. 1 is a sectional view of a linear piezoelectric motor according to an exemplary embodiment of the present disclosure.

FIG. 2 is a perspective view illustrating a coupler according to an exemplary embodiment of the present disclosure.

FIG. 3 is a perspective view of a fastening unit according to an exemplary embodiment of the present disclosure.

### DESCRIPTION OF EXEMPLARY EMBODIMENTS

Since various changes may be applied to the present disclosure and the present disclosure may have various forms, specific embodiments will be illustrated in the accompanying drawings and described in detail in the text. However, it should be understood that the present disclosure is not limited to a specific disclosure and includes all changes, equivalents, and substitutes included in the spirit and scope of the present disclosure. In description of each drawing, similar reference numerals are used for similar components.

Unless otherwise defined, all terms used herein including technical or scientific terms have the same meanings as those commonly understood by those skilled in the art to which the present disclosure belongs. Terms defined in commonly used dictionaries should be interpreted as having the same meanings in the context of the related art and may not be interpreted with ideal or excessively formal meanings, unless explicitly defined in the present application.

Hereinafter, exemplary embodiments of the present disclosure will be described in more detail with reference to the accompanying drawings.

### Embodiment

FIG. 1 is a sectional view of a linear piezoelectric motor according to an exemplary embodiment of the present disclosure.

Referring to FIG. 1, the linear piezoelectric motor has a housing 100, a lower substrate 110, a piezoelectric actuator 120, a coupler 130, a moving shaft 140, and a fastening unit 150.

The housing 100 blocks external factors such as water from penetrating into an interior thereof. In particular, a recessed part 101 and an insertion hole 102 are formed in an upper portion of the housing 100, the moving shaft 140 is drawn out from an inside to an outside of the housing through the insertion hole 102, and the fastening unit 150 is formed inside the recessed part 101. In particular, the recessed part 101 is filled with an adhesive 155 so that water does not penetrate into the recessed part 101 and the insertion hole 102. It is preferable that the adhesive 155 is formed to surround side surfaces of the fastening unit 150 formed in the recessed part 101. In order to define the recessed part 101 in which the adhesive 155 is accommodated and the fastening unit 150 is provided, a protrusion 103 is formed on a side surface of the recessed part 101.

The lower substrate 110 which is bonded to the piezoelectric actuator 120 to suppress radial vibrations of the piezoelectric actuator 120, the piezoelectric actuator 120, and the coupler 130 are formed inside the housing 100, and the moving shaft 140 passes through the housing 100.

The piezoelectric actuator 120 includes a piezoelectric material and a conductor such as a silver electrode on upper and lower surfaces thereof. The substantial shape of a dome is formed of the piezoelectric material, and the domed surfaces are coated with the conductor. The domed upper surface and the lower surface made of a piezoelectric material are coated with the conductor. The piezoelectric actuator 120 whose surfaces are coated with the conductor generates vertical vibrations by a voltage applied from an external device.

The lower substrate 110 is disposed on a side surface of the piezoelectric actuator 120. The piezoelectric actuator 120 is adhesively inserted into the lower substrate 110 that suppresses radial vibrations of the piezoelectric actuator 120, and the separation between the piezoelectric actuator 120 and the lower substrate 110 needs to be minimized. When the piezoelectric actuator 120 generates radial vibrations due to an applied voltage, the lower substrate 110 blocks horizontal vibrations or separation of the piezoelectric actuator 120 due to the radial vibrations. Thus, horizontal stress is converted into axial stress, and the displacement is enlarged so that the moving shaft 140 vibrates in a lengthwise direction. In order to restrict movement of the piezoelectric actuator 120 and block the stress to the side surface thereof, it is preferable that the lower substrate 110 is made of a material having low ductility or malleability. For example, the lower substrate 110 may be formed of a general ceramic material that is the same material as a piezoelectric body.

In particular, the lower substrate 110 needs to be firmly fixed to a bottom surface of the housing 100, has a shape in which a hole is formed in a center thereof so that a wire drawn out from a lower electrode of the piezoelectric actuator 120 is drawn out to the outside, and has an inner peripheral surface having a step so that the piezoelectric actuator 120 may be fixed. Further, a metal wire is introduced from the outside of the housing 100 through the inner space of the lower substrate 110 and is electrically connected to the bottom surface of the piezoelectric actuator 120. Further, another metal wire is also introduced from the outside of the housing 100 and is electrically connected to the upper surface of the piezoelectric actuator 120.

The coupler 130 is disposed on an upper front portion of the dome shape of the piezoelectric actuator 120. The piezoelectric actuator 120 and the moving shaft 140 may be coupled to each other through the coupler 130. In particular, the coupler 130 has a curved shape in which a lower surface and an upper surface are concave toward the center, and a concave portion of the lower surface is well matched with the upper surface of the dome-shaped piezoelectric actuator 120. In particular, the lower surface of the coupler 130 needs to be formed concavely along the shape of the dome so that a portion of the surface of the convex dome-shaped piezoelectric actuator 120 is accommodated therein.

Further, a through-hole may be formed in the coupler 130, a protrusion may be formed around the through-hole, and the protrusion may be defined as a protruding shape in the form of a screw thread.

It is preferable that the moving shaft 140 is inserted into the through-hole of the coupler 130, and the moving shaft 140 is in contact with the upper surface of the lower piezoelectric actuator 120. In particular, the moving shaft 140 may be disposed so that the lengthwise direction thereof perpendicularly intersects a tangent direction of the piezoelectric actuator 120 at an apex thereof. That is, a bottom end of the moving shaft 140 is coupled to the apex of the piezoelectric actuator 120 of the coupler 130. Further, the moving shaft 140 is in direct contact with the threaded protrusion of the coupler 130 and is firmly coupled to the piezoelectric actuator 120. It is preferable that the moving shaft 140 is in direct contact with the protrusion of the coupler 130 to be firmly coupled with the coupler 130 or the piezoelectric actuator 120. Further, the moving body is in contact with the moving shaft 140 and is linearly driven by friction with the moving shaft 140.

An adhesive 135 is introduced into a contact portion between the coupler 130 and the moving shaft 140. In particular, since the protrusion of the coupler 130 has a thread shape, the adhesive 135 advantageously fills a separation space between the coupler 130 and the moving shaft 140. The adhesive 135 is introduced into the separation space along the protrusion having a thread shape, and may completely fill the separation space.

Through this, in the linear piezoelectric motor, the adhesive 135 fills the separation space between the coupler 130 and the moving shaft 140, and an area in which the adhesive 135 adheres to the coupler 130 increases. Thus, a problem that the moving shaft 140 is separated from the piezoelectric actuator 120 is solved. Further, a portion in which the lower surface of the coupler 130 and the piezoelectric actuator 120 are in contact with each other is filled with the adhesive 135 to complete firm bonding between the coupler 130 and the piezoelectric actuator 120. Through this, the moving shaft 140 and the piezoelectric actuator 120 is firmly coupled to each other through the coupler 130.

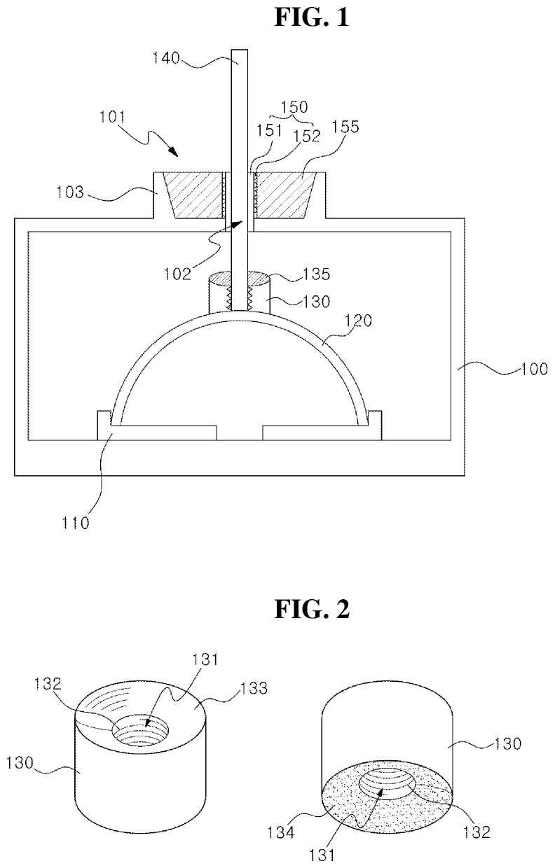

FIG. 2 is a perspective view illustrating a coupler according to an exemplary embodiment of the present disclosure.

Referring to FIGS. 1 and 2, the coupler 130 has a circular cylindrical structure manufactured through general metal processing and die casting. The coupler 130 has a through-hole 131, a protrusion 132, an upper surface 133, and a lower surface 134.

The through-hole 131 passes through the center of the coupler 130, and the moving shaft 140 is inserted through the through-hole 131. Further, it is preferable that the through-hole 131 has an upper width and a lower width which are identical to each other.

The protrusion 132 is formed in an inner wall of the coupler 130 having the through-hole 131. The protrusion 132 may be formed through mechanical processing or sanding treatment, it is preferable that a portion of the protrusion 132 protruding toward the through-hole 131 is in direct contact with the moving shaft 140, and it is preferable that a recessed portion of the protrusion 132 is filled with the adhesive 135. An uneven structure is formed through the formation of the protrusion 132, and an area in which the adhesive 135 is in contact with the coupler 130 increases. Through this, the moving shaft 140 is firmly bonded to the through-hole 131.

Further, the upper surface 133 of the coupler 130 has a concave shape. The through-hole 131 is formed at the apex of the concave shape, and a phenomenon is prevented in which the adhesive 135 overflows and flows around the coupler 130.

Further, the lower surface 134 of the coupler 130 may be formed to match a curvature of the dome shape of the piezoelectric actuator 120, and a slight gap may be formed to secure the amount of epoxy on the contact surface. That is, the curvature of the upper bonding surface of the piezoelectric actuator 120 may be slightly larger than the curvature of the lower surface 134 of the coupler 130. Through this, the bonding between the coupler 130 and the piezoelectric actuator 120 is maximized.

Further, the adhesive 135 may be introduced into a space between the lower surface 134 of the coupler 130 and the surface of the piezoelectric actuator 120 to form firm bonding between the coupler 130 and the piezoelectric actuator 120. The coupler 130 has fine unevenness by sanding the concave-shaped lower surface 134 that is bonded to an upper portion of the piezoelectric actuator 120. The contact area with the silver electrode formed on the upper surface of the piezoelectric actuator 120 is increased due to the lower surface 134 having an uneven shape, and a phenomenon in which the adhesive is expanded during curing due to the formed fine uneven structure is prevented by the principle of a sucker.

Referring back to FIG. 1, the fastening unit 150 is provided in the recessed part 101 outside the housing 100.

In particular, the fastening unit 150 has an elastic tube 151 and a tension spring 152. The moving shaft 140 may be inserted into the elastic tube 151, and the outer surface of the elastic tube 151 may be formed in contact with the tension spring 152. Further, the elastic tube 151 surrounds the surface of the moving shaft 140 but is not provided in a completely bonded form. However, the elastic tube 151 has a structure, in which a predetermined pressure may be applied to the surface of the moving shaft 140 by elasticity, and is inserted into the insertion hole 102 at an upper portion of the housing 100 together with the moving shaft 140. The insertion hole 102 may be sealed by the elastic tube 151 that may maintain an elastic shape against external pressure. In particular, since the elastic tube 151 has no adhesive force or minimal adhesive force with the moving shaft 140, vibration interference by the elastic tube 151 is minimized even when the moving shaft 140 vibrates in a lengthwise direction thereof. That is, the moving shaft 140 may pass through the inside and the outside of the housing 100 by the elastic tube 151 of the fastening unit 150, and external water does not pass through the insertion hole 102 by the elastic tube 151.

Further, the tension spring 152 presses the elastic tube 151 from the outside and acts so that the elastic tube 151 presses the moving shaft 140 without a gap. Since the pressure is applied to the elastic tube 151 in an environment in which an elastic force of the elastic tube 151 is degraded due to continuous use, the tension spring 152 may supplement the elastic force of the elastic tube 151.

The adhesive 155 fills the recessed part 101 in which the fastening unit 150 is provided. The waterproof property of the housing 100 may be further improved by the adhesive 155 filling the recessed part 101, and the fastening unit 150 is fixed to the recessed part 101 of the housing 100. In particular, the adhesive 155 filling the recessed part 101 may be formed up to a portion immediately above the uppermost end of the elastic tube 151.

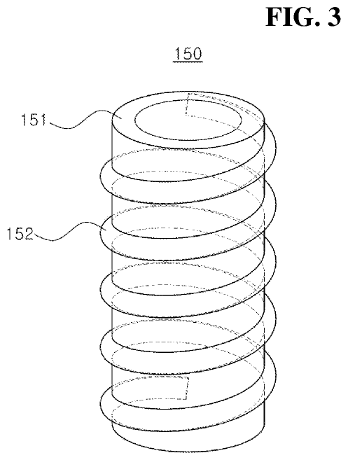

FIG. 3 is a perspective view of a fastening unit according to an exemplary embodiment of the present disclosure.

Referring to FIG. 3, the fastening unit 150 has a transparent elastic tube 151 and a metallic tension spring 152.

The elastic tube 151 of FIG. 3 may have a transparent silicone material referred to by those skilled in the art. However, the elastic tube 151 is disposed inside the metallic tension spring 152 to have a constant inner diameter and a constant outer diameter. Further, it is preferable that the inner diameter of the elastic tube 151 when the elastic tube 151 does not accommodate the moving shaft 140 is smaller than the moving shaft 140. When the moving shaft 140 is accommodated in the elastic tube 151, the elastic tube 151 is expanded, and a compressive stress is applied to the moving shaft 140 by the expansion of the inner diameter.

Further, in order to apply a continuous compressive stress, the outside of the elastic tube 151 is surrounded by the tension spring 152. The tension spring 152 has a spring shape and exerts the compressive stress toward the inner diameter. That is, although a general spring exerts a compressive force and an expansive force through the action of a spring, the tension spring 152 of FIG. 3 of the present disclosure exerts a compressive stress toward the inner diameter of the spring.

Through the above-described structure, the fastening unit 150 may prevent external moisture from penetrating into the housing due to the moving shaft passing through the housing, and does not interfere with the movement of the moving shaft vibrating in the lengthwise direction due to an excessive adhesive force.

According to the present disclosure described above, the moving shaft is firmly bonded to the piezoelectric actuator through the coupler. In particular, the protrusion having a substantially threaded shape is formed on the inner circumferential surface of the through-hole of the coupler, and a structure is formed so that the moving shaft is easily joined to the coupler. In particular, the adhesive filling a separation space between the moving shaft and the coupler may secure an increased contact area with the coupler by means of a thread-shaped protrusion. Further, the lower surface and the upper surface of the coupler are provided in a concave shape, and the lower surface is formed to match of the dome shape of the piezoelectric actuator, thereby maximizing the joining between the coupler and the piezoelectric actuator. Further, the upper surface of the coupler has a concave shape, and accommodates the adhesive so that the adhesive does not flow down the side surfaces of the coupler.

Through this, in the linear piezoelectric motor, water does not penetrate even in an underwater environment, and stable operation can be performed.

According to the present disclosure described above, a moving shaft is firmly joined to a piezoelectric actuator through the coupler. In particular, a protrusion having a substantially threaded shape is formed on the inner circumferential surface of a through-hole of a coupler, and a structure is formed in which the moving shaft is easily joined to the coupler. In particular, an adhesive filling a separation space between the moving shaft and the coupler may secure an increased contact area with the coupler by means of a thread-shaped protrusion. Further, a lower surface and an upper surface of the coupler may be provided in a concave shape, the lower surface may be formed so that the curvature is matched to the dome shape of the piezoelectric actuator, and a slight gap may be formed to secure the amount of epoxy in a contact surface. That is, a curvature of an upper adhesion surface of the piezoelectric actuator is slightly larger than a curvature of a lower portion of the coupler. Joining between the coupler and the piezoelectric actuator is maximized. Further, the upper surface of the coupler also has a concave shape, and accommodates the adhesive so that the adhesive does not flow down to the side surfaces of the coupler. A technology is provided in which as fine unevenness is formed by sanding in a curved part of the coupler adhering to an upper portion of the piezoelectric actuator, a contact area with a silver electrode formed on the piezoelectric actuator is increased, and a phenomenon in which the adhesive is expanded during curing due to the formed fine unevenness is prevented by the principle of a sucker.

Meanwhile, through the present disclosure, a well structure is formed in a boundary surface with a housing provided so that the piezoelectric actuator and the coupler avoid contact with water, and the adhesive is inserted therein to prevent water from flowing in the housing. However, separation from the moving shaft may occur due to various environmental changes in an adhesion area, that is, thermal expansion and contraction of the adhesive due to an increase in a temperature or an increase/decrease in a pressure in a closed space. In this case, a technology is provided in which in order to prevent water from flowing into the housing, a spring and a silicone tube are inserted into a part in which the adhesive is in contact with the moving shaft, and thus a waterproof effect is maximized.

Through this, in the linear piezoelectric motor, water is not penetrated even in an underwater environment, and a stable operation can be performed.

What is claimed is:

1. A linear piezoelectric motor comprising:
a housing having a recessed part and an insertion hole in an upper portion thereof;
a lower substrate fixed to a bottom surface of the housing;
a piezoelectric actuator having a dome shape that is fixed to the lower substrate and performs thickness vibration by an applied voltage;
a coupler formed on the piezoelectric actuator;
a moving shaft fixed to an upper surface of the piezoelectric actuator through a through-hole of the coupler; and
a fastening unit that is formed in the recessed part of the housing and blocks water leakage between the insertion hole and the moving shaft passing through the housing through the insertion hole.

2. The linear piezoelectric motor of claim 1, wherein the coupler comprises:
a through-hole through which the moving shaft passes; and
a protrusion defining the through-hole.

3. The linear piezoelectric motor of claim 2, wherein the protrusion has a protruding thread shape, and the protruding thread shape is in contact with the moving shaft.

4. The linear piezoelectric motor of claim 3, wherein a recessed part of the protrusion having the thread shape is filled with an adhesive.

5. The linear piezoelectric motor of claim 2, wherein a lower surface of the coupler has a concave shape to correspond to a surface shape of the piezoelectric actuator having the dome shape, and an adhesive fills a space between the lower surface of the coupler and the piezoelectric actuator.

6. The linear piezoelectric motor of claim 2, wherein an upper surface of the coupler has a concave shape, and an adhesive fills the concave shape of the upper surface and a separation space between the protrusion and the moving shaft.

7. The linear piezoelectric motor of claim 2, wherein a lower surface of the coupler has an uneven structure.

8. The linear piezoelectric motor of claim 1, wherein the fastening unit comprises:
an elastic tube that has an elastic force and applies a compressive stress to the moving shaft; and
a tension spring that has a shape surrounding an outside of the elastic tube and applies a compressive stress to the elastic tube.

9. The linear piezoelectric motor of claim 8, wherein an inner diameter of the elastic tube before the moving shaft is inserted into the elastic tube is smaller than a diameter of the moving shaft, and the elastic tube into which the moving shaft is inserted is inserted into the insertion hole.

10. The linear piezoelectric motor of claim 8, wherein a side surface of the fastening unit formed in the recessed part is filled with an adhesive.

11. A linear piezoelectric motor comprising:
a piezoelectric actuator that performs vibration by an applied voltage;
a lower substrate that fixes the piezoelectric actuator;
a moving shaft that performs vibration in a lengthwise direction by the piezoelectric actuator;
a coupler that connects the moving shaft and the piezoelectric actuator;
a housing in which the piezoelectric actuator, the lower substrate, and the coupler are accommodated and through which the moving shaft passes through an insertion hole; and
a fastening unit that is disposed in a concave recessed part of the housing, surrounds a side surface of the moving shaft, and prevents external water from penetrating into the housing.

12. The linear piezoelectric motor of claim 11, wherein the coupler comprises:
a through-hole through which the moving shaft passes; and
a protrusion defining the through-hole,
wherein the protrusion has a protruding thread shape, the protruding thread shape is in contact with the moving shaft, and a recessed part of the protrusion having the thread shape is filled with an adhesive.

13. The linear piezoelectric motor of claim 12, wherein a lower surface of the coupler has a concave shape corresponding to a surface shape of the piezoelectric actuator having a dome shape and an uneven structure having fine protrusions on a surface thereof, and an adhesive fills a space between the lower surface of the coupler and the piezoelectric actuator.

14. The linear piezoelectric motor of claim 11, wherein the fastening unit comprises:
an elastic tube that has an elastic force and applies a compressive stress to the moving shaft; and
a tension spring that has a shape surrounding an outside of the elastic tube and applies a compressive stress to the elastic tube.

15. The linear piezoelectric motor of claim 14, wherein an inner diameter of the elastic tube before the moving shaft is inserted into the elastic tube is smaller than a diameter of the moving shaft, and the elastic tube into which the moving shaft is inserted is inserted into the insertion hole.
